(19) United States
(12) Patent Application Publication
(10) Pub. No.: US 2009/0223554 A1
(43) Pub. Date: Sep. 10, 2009

(54) Dual Sided Photovoltaic Package

(75) Inventor: Paul R. Sharps, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/042,949

(22) Filed: Mar. 5, 2008

(51) Int. Cl. H01L 31/052; H01L 31/06

(52) U.S. Cl. 136/246; 136/255

(57) ABSTRACT

A double-sided photovoltaic package with an incident photovoltaic cell and a reflective photovoltaic cell. Both photovoltaic cells have a corresponding absorbing surface for absorbing solar radiation. The incident photovoltaic cell and the reflective photovoltaic cell are arranged so that when the absorbing surface of the incident photovoltaic cell is located to receive incident non-reflected solar radiation the absorbing surface of the reflective photovoltaic cell is located to receive reflected solar radiation. The structure of the incident photovoltaic cell is adapted to convert non-reflected light to electrical energy and the structure of the reflective photovoltaic cell is adapted to convert reflected light to electrical energy. Additionally, in the preferred embodiment, the incident photovoltaic cell and the reflective photovoltaic cell both comprise inverted metamorphic multijunction photovoltaic cells. Furthermore, a plurality of double-sided photovoltaic packages according to the present invention may be interconnected in a string formation and mounted on a transparent panel to form an array.

### TECHNICAL FIELD

The present invention relates to solar power generation. More specifically, the present invention provides a new photovoltaic package with a high power output per unit area and a flexible structure that is suitable for space applications.

### BACKGROUND OF THE INVENTION

It is known to produce photovoltaic cells for space applications in order to provide electric power for devices, such as, for example, a satellite. It is also known to optimize known photovoltaic cells to absorb solar radiation over a certain portion of the electromagnetic spectrum. An optimized photovoltaic cell converts incident solar radiation with the target portion of the electromagnetic spectrum into electricity with improved efficiency. Accordingly, it is known to optimize photovoltaic cells to absorb the specific spectrum of solar radiation emitted directly from the Sun. The process of optimization involves selecting the material composition and construction of the photovoltaic cell according to the target portion of the electromagnetic spectrum.

As with almost any design exercise, designing photovoltaic cells for use with a satellite involves balancing a number of conflicting factors. On the one hand, the greater the amount of electrical energy available to power a number of electronic devices, such as, mechanical actuators and communications equipment, the better. On the other hand, the smaller the mass the better to reduce the launch payload. These two requirements are often in conflict because, generally, the more power a photovoltaic cell (or array of cells) is capable of producing the larger the cell (or array of cells) is and, therefore, the greater its mass. Accordingly, an important objective in the design of a photovoltaic cell for use with a satellite is to increase electricity generation while decreasing weight. Power density, also known as specific power, is a measure of electricity generated per unit mass, area or volume, and provides a useful measure of the performance of a photovoltaic cell design.

It is also known that photovoltaic cells for space applications are preferably flexible for a number of reasons. For example, the launch process creates many strong vibrations and causes photovoltaic cells to rub against, and impact with, other components. Furthermore, whilst operating in space, flexible photovoltaic cells are capable of absorbing small impacts from passing debris.

Much of the development in photovoltaic cell technology has concentrated on different ways of manipulating designs of photovoltaic cells to optimize power density. It is known that the performance of a photovoltaic cell may be improved by selecting particular material compositions and selecting particular arrangements of the chosen materials during the construction of the photovoltaic cell.

For example, photovoltaic cells are known to have been developed for space applications that consist of multiple thin-films of semiconductor material such as, Gallium Arsenide (GaAs), Germanium (Ge) and Indium Gallium Phosphide (GaInP₂). Accordingly, the semiconductor materials are carefully chosen to absorb nearly the entire solar spectrum emitted from the Sun, thus generating electricity from as much of the solar radiation as possible. Additionally, by using multiple thin-films, the amount of light absorbing material required in creating a photovoltaic cell is reduced and, therefore, the weight of the cell is reduced.

Double-sided, also known as dual-sided, photovoltaic packages comprising two photovoltaic cells, provide another known technique of improving the power generating capability of a photovoltaic cell while reducing the commensurate weight increase. Typically, a photovoltaic cell has a planar shape and only one of the two planes is capable of converting incident solar radiation into electricity. Double-sided photovoltaic packages are capable of converting solar radiation incident on both plane surfaces into electricity. One advantage of double-sided photovoltaic packages is that they have the potential to absorb approximately twice as much solar radiation as traditional single-sided cells. Additionally, the weight of a double-sided cell is less than twice the weight of a single-sided cell as some elements of construction are shared by both sides. Unfortunately, however, known double-sided cells often have a low power density and are too rigid for space applications.

### SUMMARY OF THE INVENTION

In order to address the above problems, an embodiment of the present invention provides a double-sided photovoltaic package that has a high power density and is sufficiently flexible to be suitable for space applications.

Generally, the invention provides for a double-sided photovoltaic package having two energy absorbing surfaces arranged so that when deployed, for example in a satellite, one of the surfaces will absorb light emitted directly by the Sun whereas the other of the surfaces will absorb light reflected by the Earth. Preferably, each of the absorbing surfaces has a structure adapted to absorb a spectrum of the corresponding light that that surface receives.

More particularly, the present invention provides a double-sided photovoltaic package having an incident photovoltaic cell and a reflective photovoltaic cell, each photovoltaic cell having a corresponding absorbing surface for absorbing solar radiation; the incident photovoltaic cell and the reflective photovoltaic cell being arranged so that when the absorbing surface of the incident photovoltaic cell is located to receive incident non-reflected solar radiation and the absorbing surface of the reflective photovoltaic cell is located to receive reflected solar radiation; wherein a structure of the incident photovoltaic cell is adapted to convert non-reflected light to electrical energy and a structure of the reflective photovoltaic cell is adapted to convert reflected light to electrical energy. In the preferred embodiment, the incident photovoltaic cell and the reflective photovoltaic cell both comprise inverted metamorphic photovoltaic cells.

Inverted metamorphic multijunction (IMM) solar cells consist of a combination of compound semiconductors that enable the production of solar cells with comparable performance to other solar cells manufactured from more traditional materials but at about one fifteenth of the thickness.

It is a primary advantage of the present invention that the double sided photovoltaic package is capable of converting solar radiation incident on both incident and reflective photovoltaic cells and thereby, optimizes power generation and optimizes weight. Another advantage of the present invention is that it has a flexible structure.

It is preferable that the reflective photovoltaic cell is located on an opposite side to the incident photovoltaic cell. Additionally it is preferable that the structure of the incident photovoltaic cell is optimized for converting non-reflected solar light to electrical energy and wherein the structure of the reflected photovoltaic cell is optimized for converting reflected solar light to electrical energy.

It is preferable that a conductive adhesive is sandwiched between the incident photovoltaic cell and the reflective photovoltaic cell to provide a common ground to both photovoltaic cells. Furthermore, it is preferable that the absorbing surfaces of the incident and reflective photovoltaic cells are coated with a flexible transparent membrane.

It is preferable that the incident photovoltaic cell and the reflective photovoltaic cell are each sandwiched between a front metal contact and a back metal contact so that each absorbing surface abuts a corresponding front metal contact. Additionally, it is preferable that a flexible dielectric adhesive is sandwiched between the incident photovoltaic cell and the reflective photovoltaic cell, and the flexible dielectric adhesive abuts the back metal contact of the incident photovoltaic cell and the reflective photovoltaic cell. Finally, it is preferable that the front metal contact of both the incident photovoltaic cell and the reflective photovoltaic cell is coated with a flexible transparent membrane.

In different embodiments the incident and the reflective photovoltaic cells are optionally three junction, four junction or five junction photovoltaic cells.

In an embodiment, a plurality of double-sided photovoltaic packages according to the present invention are combined to form an array. In another embodiment, the double-sided photovoltaic packages are arranged in a string formation wherein at least one cell is interconnected to two adjacent cells. In a another embodiment the incident photovoltaic cell of at least one double-sided package is interconnected to an incident photovoltaic cell of each adjacent double-sided package and the reflective photovoltaic cell of the at least one double-sided package is interconnected to the reflective photovoltaic cell of each adjacent double-sided package. In a further embodiment, the array is mounted on a transparent panel.

An embodiment of the present invention provides a photovoltaic cell and an array of photovoltaic cells for use in a space application including satellite applications and the like.

### BRIEF DESCRIPTION OF THE DRAWINGS

An overview of the operation of the invention, together with a description of a number of embodiments thereof, presented by way of example only, will now be made with reference to the accompanying drawings, wherein like reference numerals refer to like parts, and wherein:

FIG. 1 is a pictorial representation of a typical environment in which an embodiment of the present invention is intended to operate.

FIG. 2 is a schematic cross-section view of a photovoltaic package according to a preferred embodiment.

FIG. 3 is a detailed schematic view of an incident or a reflective photovoltaic cell of the preferred embodiment.

FIG. 4 is another detailed schematic view of an incident or a reflective photovoltaic cell of the preferred embodiment.

FIG. 5 is a schematic cross-section view of an array of photovoltaic packages.

FIG. 6 is a schematic cross-section view of a photovoltaic package according to an alternative embodiment.

### OVERVIEW OF THE OPERATION OF THE INVENTION

Before proceeding to describe a particular embodiment of the invention, a brief overview of the operation of embodiments of the invention will first be undertaken. The present invention provides a double-sided photovoltaic package comprising an incident photovoltaic cell and a reflective photovoltaic cell. An adhesive is sandwiched in-between the incident photovoltaic cell and the reflective photovoltaic cell.

The incident photovoltaic cell converts incident solar radiation into electric power with maximum efficiency for incident non-reflective radiation. The reflective photovoltaic cell is optimized so that it converts incident solar radiation into electric power with maximum efficiency for incident reflected solar radiation.

A plurality of double-sided photovoltaic packages according to the present invention are arranged in a string formation and mounted on a transparent panel to form an array. At least one double-sided photovoltaic package in the array is connected in series with two adjacent double-sided packages. Moreover, the incident photovoltaic cell of the at least one double-sided package is connected in series with the incident photovoltaic cell of each adjacent double-sided package, and the reflective photovoltaic cell of the at least one double-sided package is connected in series with the reflective photovoltaic cell of each adjacent double-sided package.

### Description of the Embodiments

A preferred embodiment of the invention will now be described in detail with reference to the accompanying drawings, wherein like reference numerals relate to like components.

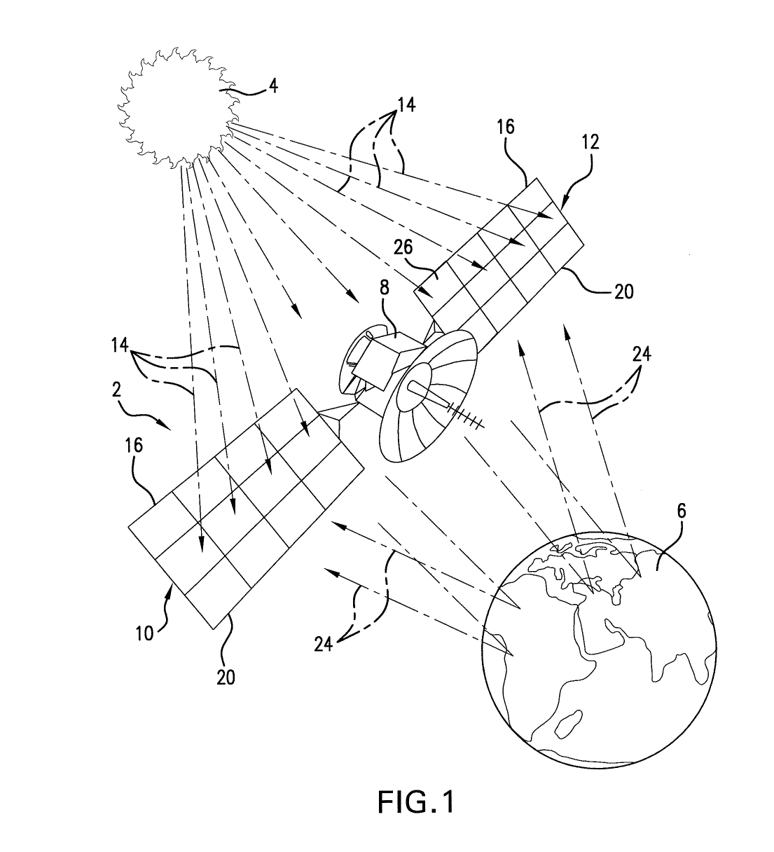

FIG. 1 depicts a typical environment in which an embodiment of the present invention is intended to operate. A satellite 2 is located in-between the Sun 4 and the Earth 6. The satellite 2 comprises a control unit 8 and two photovoltaic arrays 10 and 12. The control unit 8 is responsible for controlling the functionality of the satellite 2 and, although it is required for the satellite to operate, it does not form part of the present invention and, therefore, the control unit 8 will not be discussed in detail.

The satellite 2 is positioned and arranged so that direct solar radiation 14 from the Sun 4 is incident on a top surface 16 of photovoltaic arrays 10 and 12. Furthermore, a bottom surface 20 of photovoltaic arrays 10 and 12 have incident upon them indirect solar radiation 24 from the Sun 4 that has been reflected from the Earth 6. The photovoltaic arrays 10 and 12 each comprise a plurality of double-sided photovoltaic packages 26.

In operation, the double-sided photovoltaic packages 26 of photovoltaic arrays 10 and 12 absorb direct solar radiation 14 and indirect solar radiation 24, and convert the absorbed solar radiation into electricity which is used to power the control unit 8 so that the satellite 2 functions.

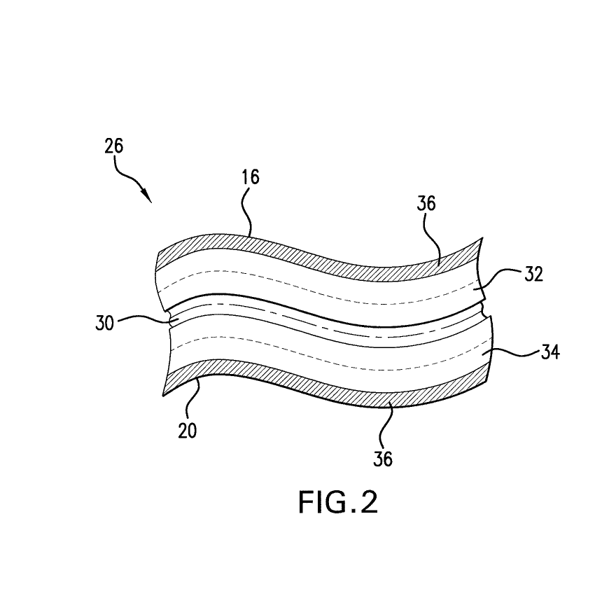

FIG. 2 shows a cross-section view of a single double-sided photovoltaic package 26 according to a preferred embodiment. The double-sided photovoltaic package 26 comprises a conductive adhesive layer 30 sandwiched in-between an upper photovoltaic cell 32 and a lower photovoltaic cell 34. A flexible transparent membrane 36 is located on the solar radiation absorbing outer surface of both the upper cell 32 and the lower cell 34. Cells 32 and 34 are negative-positive junction photovoltaic cells and both are orientated with positive-type semiconductor material abutting the adhesive layer 30 and negative-type semiconductor material abutting the flexible transparent membrane 36. The upper cell 32 and the lower cell 34 are both inverted metamorphic (IMM) photovoltaic cells.

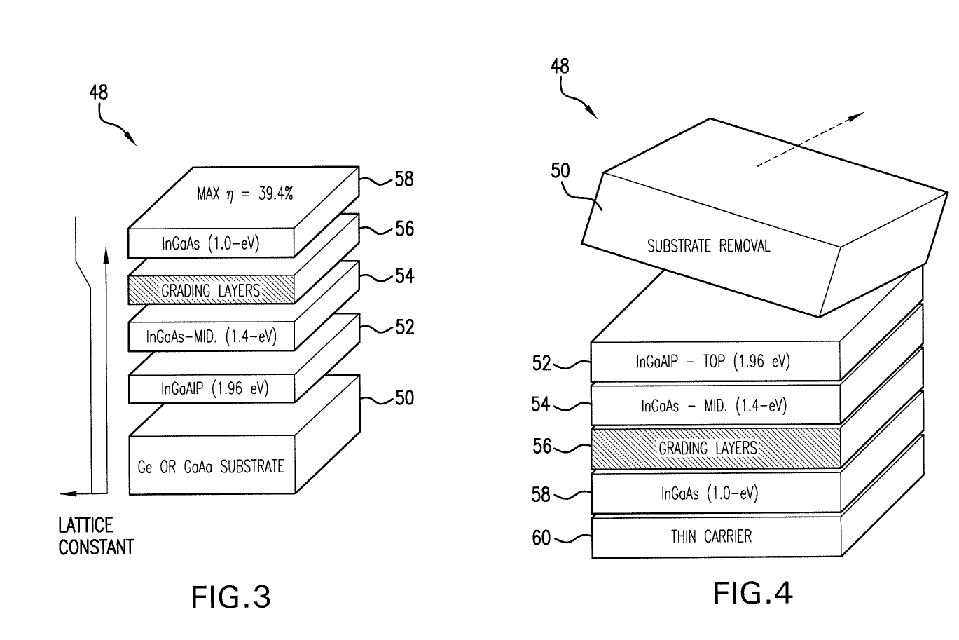

FIG. 3 and FIG. 4 illustrate in detail an exemplary IMM structure 48. As seen more particularly in FIG. 3, the IMM structure 48 comprises a number of different semiconductor layers that are fabricated in an inverted order. The first semiconductor region is a Germanium (Ge) substrate 50. In an alternative embodiment the substrate 50 may be Gallium Arsenide (GaAs). An Indium Gallium Aluminum Phosphate (InGaAlP) layer 52 is grown on top of substrate 50. An Indium Gallium Arsenide (InGaAs) layer 54 is grown on top of layer 52. A grading layer 56 is grown on top of layer 54. Finally, an Indium Gallium Arsenide (InGaAs) layer 58 is grown on top of layer 56.

As seen more particularly in FIG. 4, after fabrication, the IMM structure 48 is orientated so that the substrate layer 50 forms a top outer surface and the InGaAs layer 58 forms a bottom outer surface. Finally, a thin carrier layer 60, made of Kapton®, is attached to the outer surface of layer 58 and the substrate layer 50 is removed to expose the InGaAlP layer 52. In operation, solar radiation incident on the outer surface of layer 52 is converted into electricity by the IMM structure 48 and the resultant current is transported via the thin carrier 60.

The material composition of the upper cell 32 is designed so that the upper cell 32 converts directly incident solar radiation 14 from the Sun 4 into electric power with optimized efficiency. The material composition of the lower cell 34 is designed so that the lower cell 34 converts solar radiation 14 from the Sun 4 that has been subsequently reflected from the Earth 6 into electric power with maximum efficiency. Therefore, the upper cell 32 may be considered the incident photovoltaic cell and the lower cell 34 may be considered the reflective photovoltaic cell.

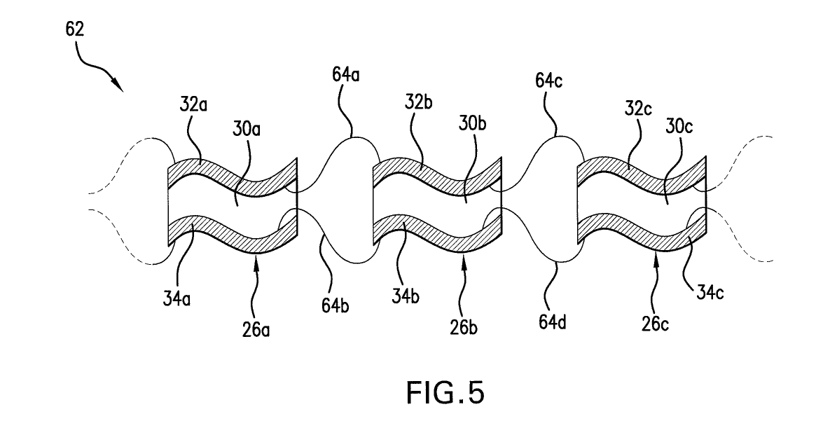

FIG. 5 illustrates how double-sided photovoltaic packages 26a, 26b and 26c are connected together in a string 62 to form the photovoltaic arrays 10 and 12. With the exception of the first double-sided package (not shown) and the last double-sided package (not shown) of the string 62, each double-sided package (including 26a, 26b and 26c) in the string 62 is positioned adjacent to two other double-sided packages. The upper cell 32a, 32b or 32c of each double sided photovoltaic package 26a, 26b or 26c is connected to the upper cells 32a, 32b or 32c of each adjacent double-sided package 26a, 26b or 26c by interconnects 64a, 64b, 64c or 64d. The photovoltaic arrays 10 and 12 are formed by laying and fixing the string 62 on to a transparent rectangular panel (not shown) so that the string 62 covers the entire surface area of the panel.

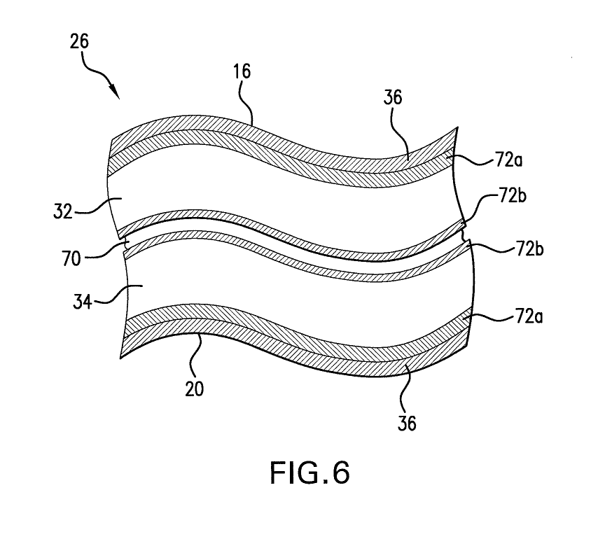

FIG. 6 illustrates a modification to the double-sided photovoltaic package 26 to form an alternative embodiment. In the alternative embodiment, the conductive adhesive layer 30 of FIG. 2 is substituted with a dielectric adhesive layer 70, and the upper photovoltaic cell 32 and the lower photovoltaic cell 34 are coated on their upper surface with a front metal contact layer 72a and on their lower surface with a back metal contact layer 72b. An advantage of the alternative embodiment is that it is more suitable for stringing together to form the photovoltaic arrays 10 and 12.

It is an advantage of both embodiments of FIGS. 5 and 6 that photovoltaic arrays comprising double-sided photovoltaic packages according to the present invention simultaneously use solar radiation direct from the Sun and solar radiation from the Sun that has been subsequently reflected from the Earth. Furthermore, because both sides of the photovoltaic array are capable of converting solar radiation into electric power, the power generated per unit area of the double-sided array is higher than a single-sided photovoltaic array.

By way of an example, the following table provides calculated values for the power density of two theoretical photovoltaic cells. The first cell, cell 1, is a single-sided IMM photovoltaic cell optimized for absorbing solar radiation directly from the Sun. The second cell, cell 2, is a double-sided IMM photovoltaic package, having an incident photovoltaic cell optimized for absorbing solar radiation directly from the Sun and a reflective photovoltaic cell optimized for absorbing solar radiation that has been reflected from the Earth. Both cells have a 0.25 mm Kapton® carrier layer and are 40% efficient.

| | Power Density |
|---|---|
| Cell 1 | 3165 W/kg |
| | 540 W/m² |
| Cell 2 | 2439 W/kg |
| | 810 W/m² |

Table indicating the power density of two theoretical photovoltaic cells

The calculated values for the power density reveal that the power per weight of the double-sided IMM photovoltaic package is less than the single-sided cell but the power per area of the double-sided package is greater than the single-sided cell. The power per weight value of the double-sided package is less than the single sided cell because the weight of the double-sided package includes the weight of the reflective photovoltaic cell. Additionally, the amount of power generated by the reflective photovoltaic cell is less than the incident photovoltaic cell because the intensity of the solar radiation reflected from the Earth is less than the intensity of the solar radiation absorbed directly from the Sun. Therefore, the amount of energy available in the reflected solar radiation that can be converted into electrical energy is less than the amount of energy available in the solar radiation absorbed directly from the Sun.

The power per area of the double-sided cell is greater than the single-sided cell because the area of the two cells are roughly the same; however, the double-sided cell is able to use a much higher proportion of its area to convert incident solar radiation into electrical energy.

1. A double-sided photovoltaic package having an incident photovoltaic cell and a reflective photovoltaic cell, each photovoltaic cell having a corresponding absorbing surface for absorbing solar radiation;
the incident photovoltaic cell and the reflective photovoltaic cell being arranged so that when the absorbing surface of the incident photovoltaic cell is located to receive incident non-reflected solar radiation and the absorbing surface of the reflective photovoltaic cell is located to receive reflected solar radiation;
wherein a structure of the incident photovoltaic cell is adapted to convert non-reflected light to electrical energy and a structure of the reflective photovoltaic cell is adapted to convert reflected light to electrical energy.

2. A double-sided photovoltaic package according to claim 1 wherein the incident photovoltaic cell and the reflective photovoltaic cell both comprise inverted metamorphic multijunction photovoltaic cells.

3. A double-sided photovoltaic package according to claim 1 wherein the reflective photovoltaic cell is located on an opposite side to the incident photovoltaic cell.

4. A double-sided photovoltaic package according to claim 1 wherein the structure of the incident photovoltaic cell is optimized for converting non-reflected solar light to electrical energy and wherein the structure of the reflected photovoltaic cell is optimized for converting reflected solar light to electrical energy.

5. A double-sided photovoltaic package according to claim 1, wherein a conductive adhesive is sandwiched between the incident photovoltaic cell and the reflective photovoltaic cell to provide a common ground to both photovoltaic cells.

6. A double-sided photovoltaic package according to claim 5, wherein the absorbing surfaces of the incident and reflective photovoltaic cells are coated with a flexible transparent membrane.

7. A double-sided photovoltaic package according to claim 1, wherein the incident photovoltaic cell and the reflective photovoltaic cell are each sandwiched between a front metal contact and a back metal contact, and each absorbing surface of each cell abuts a corresponding front metal contact.

8. A double-sided photovoltaic package according to claim 7, wherein a flexible dielectric adhesive is sandwiched between the incident photovoltaic cell and the reflective photovoltaic cell, and the flexible dielectric adhesive abuts the back metal contacts of the incident photovoltaic cell and of the reflective photovoltaic cell.

9. A double-sided photovoltaic package according to claim 8, wherein the front metal contacts of both the incident photovoltaic cell and the reflective photovoltaic cell are coated with a flexible transparent membrane.

10. A double-sided photovoltaic package according to claim 9, wherein the incident and the reflective photovoltaic cells are three junction photovoltaic cells.

11. A double-sided photovoltaic package according to claim 9, wherein the incident and the reflective photovoltaic cells are four junction photovoltaic cells.

12. A double-sided photovoltaic package according to claim 9, wherein the incident and the reflective photovoltaic cells are five junction photovoltaic cells.

13. A double-sided photovoltaic package according to claim 9, wherein the incident and the reflective photovoltaic cells comprise negative type semiconductor on positive type semiconductor photovoltaic cells, and wherein the negative type material provides the light absorbing surface.
